(19) United States
(12) Patent Application Publication
(10) Pub. No.: US 2010/0288730 A1
(43) Pub. Date: Nov. 18, 2010

(54) Vacuum Processing Apparatus And Vacuum Processing Method Using The Same

(76) Inventors: Toru Ito, Kudamatsu-shi (JP); Kotaro Fujimoto, Kudamatsu-shi (JP); Eiji Matsumoto, Kudamatsu-shi (JP); Atsushi Yoshida, Kudamatsu-shi (JP); Kouta Tanaka, Shunan-shi (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 12/844,268

(22) Filed: Jul. 27, 2010

Related U.S. Application Data
(62) Division of application No. 11/772,850, filed on Jul. 3, 2007.

(30) Foreign Application Priority Data
Jan. 12, 2007 (JP) 2007-004023

(51) Int. Cl. C23F 1/00; C23C 16/50

(52) U.S. Cl. 216/67; 427/569

(57) ABSTRACT

The invention provides a vacuum processing chamber comprising a particle removing function and capable of improving the yield and process efficiency for processing samples. The vacuum processing apparatus for transferring and processing samples comprises a processing chamber 207 within a vacuum reactor 103 and a transfer chamber 217 which are communicated via a passage having a gate valve 218, wherein the apparatus further comprises a control unit 234 for performing control upon transferring a sample to be processed between the processing chamber 207 and the transfer chamber 217 by setting the opening of a variable valve 230 for controlling pressure disposed below the vacuum reactor 103 to a predetermined opening so as to decompress the interior of the vacuum reactor, and thereafter, without varying the opening of the variable valve 230 for controlling pressure, supplying a predetermined amount of gas through a feed hole 235 into the vacuum reactor 207 so as to create a gas flow, opening the gate valve 218 to transfer the sample, then closing the gate valve 218 and stopping the feeding of gas after the transfer of the sample has been completed.

### CROSS REFERENCE TO RELATED APPLICATION

This application is a divisional application of U.S. application Ser. No. 11/772,850, filed Jul. 3, 2007, the contents of which are incorporated herein by reference.

The present application is based on and claims priority of Japanese patent application No. 2007-004023 filed on Jan. 12, 2007, the entire contents of which are hereby incorporated by reference.

### BACKGROUND OF THE INVENTION

1. Field of the Invention

The present invention relates to a vacuum processing apparatus comprising a vacuum reactor including a processing chamber disposed within the reactor for processing a sample placed therein by generating plasma within the interior of the decompressed vacuum reactor, and a transfer reactor connected to the vacuum reactor having a valve for opening and closing a passage therebetween, and specifically, to a vacuum processing apparatus having a mechanism for reducing the amount of particles stuck to the sample when opening and closing the passage and transferring the sample. Furthermore, the present invention aims at providing a vacuum processing method using the above vacuum processing apparatus for reducing the amount of particles stuck to the sample when transferring the sample between the vacuum reactor and the transfer reactor.

2. Description of the Related Art

A major problem in the fabricating process of semiconductor devices is the deterioration of yield, and it is an important challenge to reduce particles which are a significant cause of yield deterioration. There are many causes for the generation of particles, and various measures have been taken conventionally. For example, major generation sources of particles in dry etching are the reaction products and etching gas components deposited within the processing chamber, and when such deposits come off, they become particles. Along with the recent high-integration and miniaturization of devices, highly depositive gases are used as the etching gas to control the processing profile of patterns on the substrate, and therefore, the generated reaction products easily deposit within the processing chamber as deposits. Further, along with the high-integration and miniaturization of the devices, the particle size of particles causing deterioration of yield has also miniaturized, and the demand for reducing particles has become significantly high.

The cause in which the deposits on the walls come off differs according to the properties of the deposits and the like, but there is a common recognition in the field of semiconductor device fabrication that the main cause thereof is the opening and closing of the gate valve and the variation of pressure within the processing chamber caused by the opening and closing of the gate valve during transferring of samples to the processing chamber. Moreover, according to an example in which pressure is added by feeding Ar gas which is an inert gas into the transfer chamber to suppress diffusion of corrosive gas used in the processing chamber, there is a drawback in that the pressure variation during opening and closing of the gate valve is further increased (refer for example to Japanese Patent Application Laid-Open Publication No. 4-100222, hereinafter referred to as patent document 1). To cope with these problems, in addition to the attempt to reduce the amount of deposits, there are attempts to improve the structure of the gate valve, the opening and closing mechanism of the valve and the speed of opening and closing the valve.

One means for suppressing the influence of pressure variation during opening and closing of the gate valve is disclosed for example in Japanese Patent Application Laid-Open Publication No. 7-211761, hereinafter referred to as patent document 2, which suppresses the pressure variation during opening and closing of the gate valve by providing an opening and closing valve disposed in a bypath connecting a common transfer chamber and the processing chamber, feeding N₂ gas within the common transfer chamber through the bypath into the processing chamber prior to opening and closing the gate valve so as to either set the pressure within the chamber equal to or slightly lower than the pressure in the common transfer chamber, and thereafter, performing opening and closing operation of the gate valve.

However, according to the above-disclosed art, a bypath communicating the two connected chambers is provided and the pressure difference is controlled to a predetermined value via the flow path resistance when gas is passed through the bypath, but according to such arrangement, there is much time required for controlling the pressure difference to a predetermined value, and too much time is required for transferring the sample, so that the process efficiency is deteriorated.

Moreover, the pressure difference between the two chambers can be reduced through the above method, but the gas flow formed during opening of the gate valve is flown from the transfer chamber having a high pressure toward the processing chamber through a gate valve opening having small flow path resistance, and further according to the above method, the bypath is closed after opening the gate valve, so that the gas flow from the transfer chamber to the processing chamber is continued until the gate valve is closed, and actually, there occurs a drawback in that the reaction products stuck to the inner surface of the processing chamber and the reaction products existing near the surface thereof are moved via the gas flow toward the sample stage and are stuck to the surface of the sample.

### SUMMARY OF THE INVENTION

The object of the present invention is to provide a vacuum processing apparatus having a particle removing function for improving the yield of the sample being processed.

Another object of the present invention is to provide a vacuum processing apparatus having a particle removing function for improving the processing efficiency of the sample being processed.

Yet another object of the present invention is to provide a vacuum processing method adopting a sample transferring method capable of suppressing the generation of particles during transfer of the samples, to improve the yield of the sample to be processed and to improve the processing efficiency.

The above-mentioned objects are realized by providing a vacuum processing apparatus comprising: a processing chamber disposed within a vacuum reactor and having plasma generated therein; a sample stage disposed at a lower portion within the processing chamber for mounting on an upper surface thereof a sample to be processed; a gas feed mechanism disposed at an upper portion of the processing chamber and having a feed hole for feeding processing gas into the processing chamber; a transfer reactor connected to the vacuum reactor for having the sample to be processed transferred in the decompressed interior thereof; a gate valve for opening and closing a passage communicating the transfer reactor and the vacuum reactor; and a control unit for setting a variable valve for controlling pressure disposed below the vacuum reactor to a predetermined opening and decompressing the interior of the vacuum reactor upon transferring the sample to be processed between the vacuum reactor and the transfer reactor, feeding a predetermined amount of gas through the feed hole into the vacuum reactor and forming a gas flow without varying the opening of the variable valve for controlling pressure, opening the gate valve in this state to transfer the sample, closing the gate valve after transferring the sample and stopping the feeding of gas thereafter.

Further, the above objects are realized by providing an apparatus for setting, upon transferring the sample to be processed between the vacuum reactor and the transfer reactor, a variable valve for controlling pressure disposed below the vacuum reactor to a predetermined opening and decompressing the interior of the vacuum reactor, and thereafter, feeding a predetermined amount of gas through the feed hole into the vacuum reactor and forming a gas flow without varying the opening of the variable valve for controlling pressure, wherein the gas is either Ar gas or N₂ gas, the formed gas flow has a flow rate of 200 ml/min or greater, and the pressure within the vacuum reactor is lower than the pressure within the transfer reactor.

Furthermore, the above objects are realized by providing a vacuum processing method using a vacuum processing apparatus comprising: a processing chamber disposed within a vacuum reactor and having plasma generated therein; a sample stage disposed at a lower portion within the processing chamber for mounting on an upper surface thereof a sample to be processed; a gas feed mechanism disposed at an upper portion of the processing chamber and having a feed hole for feeding processing gas into the processing chamber; a transfer reactor connected to the vacuum reactor for having the sample to be processed transferred in the decompressed interior thereof; and a gate valve for opening and closing a passage communicating the transfer reactor and the vacuum reactor; wherein the vacuum processing method comprises, upon transferring the sample to be processed between the transfer reactor and the vacuum reactor; setting a variable valve for controlling pressure disposed below the vacuum reactor to a predetermined opening so as to decompress the interior of the vacuum reactor; feeding a predetermined amount of gas through the feed hole into the vacuum reactor and forming a gas flow without varying the opening of the variable valve for controlling pressure; opening the gate valve in this state to transfer the sample, closing the gate valve after transferring the sample and stopping the feeding of gas thereafter.

Moreover, the above objects are realized by providing the vacuum processing method using a vacuum processing apparatus according to the above, wherein the gas fed into the vacuum reactor is either Ar gas or N₂ gas, the formed gas flow has a flow rate of 200 ml/min or greater, and the pressure within the vacuum reactor is lower than the pressure within the transfer reactor connected thereto.

Even further, the above objects are realized by providing the vacuum processing method using a vacuum processing apparatus according to the above, wherein the transfer of the sample is started at least when two seconds has passed after forming the gas flow.

### BRIEF DESCRIPTION OF THE DRAWINGS

FIG. 1 shows the structure of a processing apparatus according to one embodiment of the present invention;

FIG. 2 shows a schematic view of the processing apparatus according to one embodiment of the present invention;

FIG. 3A shows a particle counting step in which Ar gas is not supplied during an examination to reduce particles according to one embodiment of the present invention;

FIG. 3B shows a particle counting step in which Ar gas is supplied during an examination to reduce particles according to one embodiment of the present invention;

FIG. 4 shows the result of counting the number of particles with and without supplying Ar gas according to one embodiment of the present invention;

FIG. 5 shows the waiting time dependency when Ar gas is supplied according to one embodiment of the present invention;

FIG. 6 shows an Ar gas flow rate dependency when Ar gas is supplied according to one embodiment of the present invention;

FIG. 7 shows a variable valve opening dependency when Ar gas is supplied according to one embodiment of the present invention;

FIG. 8 shows a relational chart showing the relationship between the number of particles and the difference between the pressure chamber pressure and the vacuum transfer chamber pressure when Ar gas is supplied according to one embodiment of the present invention;

FIG. 9 shows the position for adhering a particle source when Ar gas is supplied according to one embodiment of the present invention;

FIG. 10 shows the result of counting the number of particles with and without supplying Ar gas when the position for adhering the particle source is changed to the side surface of the sample stage according to one embodiment of the present invention; and

FIG. 11 shows the result of counting the number of particles with and without supplying Ar gas when the position for adhering the particle source is changed to the circumference of the variable valve according to one embodiment of the present invention.

### DETAILED DESCRIPTION OF THE PREFERRED EMBODIMENTS

Now, a preferred embodiment of the present invention will be described with reference to the drawings.

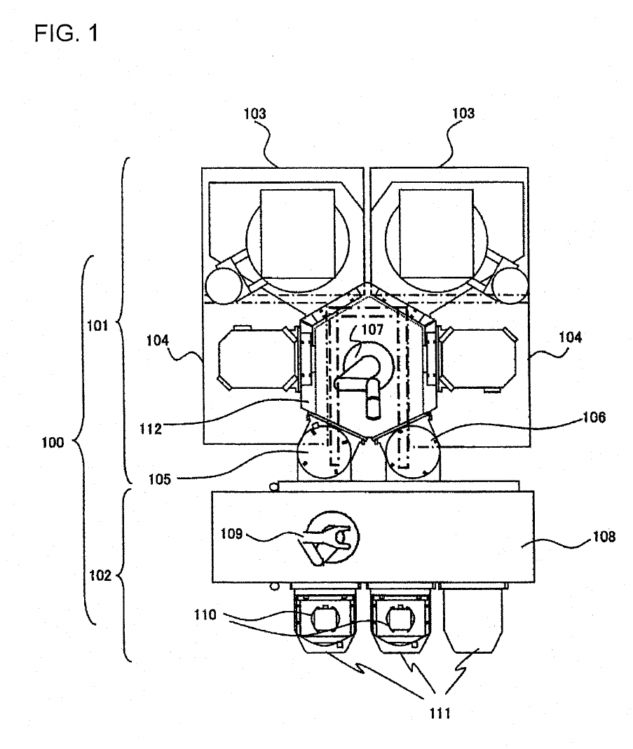

FIG. 1 is a schematic view of a vacuum processing apparatus 100 according to an embodiment of the present invention. The vacuum processing apparatus 100 illustrated in FIG. 1 is roughly divided into a vacuum block 101 and an atmospheric block 102. The atmospheric block 102 includes an atmospheric transfer reactor 108 having an atmospheric transfer robot 109, and on the front side of the atmospheric transfer reactor 108 is disposed a plurality of loading platforms 111 on which are placed a cassette 110 each capable of storing a plurality of samples such as semiconductor wafers and other substrates to be processed in the vacuum processing apparatus 100. The vacuum block 101 comprises a vacuum transfer reactor 112 having a vacuum transfer robot 107 placed therein, and disposed around the side walls of the vacuum transfer reactor 112 are a plurality of vacuum reactors 103 including a processing chamber with a vacuumed interior in which the samples being transferred are subjected to etching, a plurality of vacuum reactors 104 including a processing chamber with a vacuumed interior in which the samples being transferred are subjected to ashing, a load-lock chamber 105 and an unload-lock chamber 106 for handing over the samples between the atmospheric block and the vacuum block.

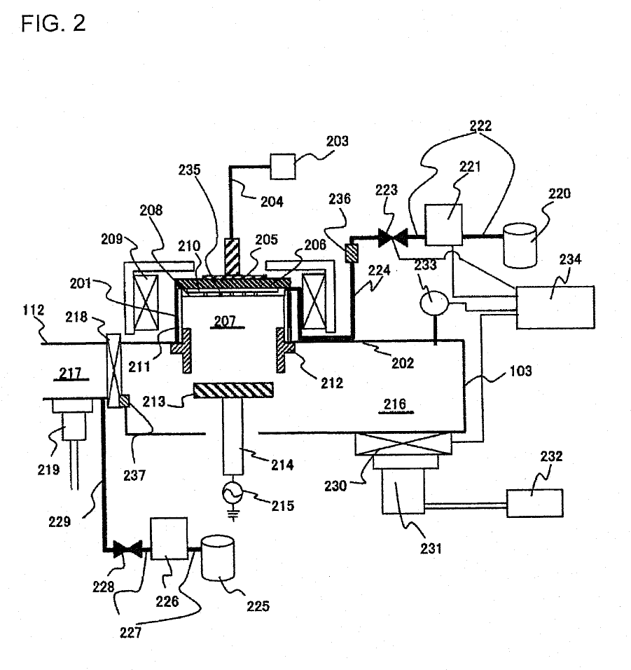

FIG. 2 is a schematic view showing the vacuum reactor 103 and the circumferential structure thereof of the vacuum processing apparatus 100 illustrated in FIG. 1. As illustrated in FIG. 2, the vacuum reactor 103 includes a processing chamber 207 defined by processing reactors 201 and 202 and a top of reactor 206 forming the upper portion of the processing reactor 201. The top of reactor 206 has an antenna 205 disposed at an upper portion thereof, and to the antenna 205 is connected a waveguide means 204 such as a coaxial cable, which is connected to an electromagnetic wave source 203 for forming electromagnetic waves in the UHF band. The conducted electromagnetic waves are introduced via the antenna 205 to the processing chamber 207 and the vacuum chamber 216 disposed within the processing reactors 201 and 202. Further, electromagnetic fields generated via a solenoid coil 209 disposed around the processing reactor 201 are supplied to the processing chamber 207 and the vacuum chamber 216.

A shower plate 208 is disposed under the top of reactor 206 with a given clearance therebetween and facing the inner side of the processing chamber 207. The shower plate 208 has multiple holes communicating the clearance and the inner side of the processing chamber 207, which constitute gas feed holes 235 for introducing processing gas into the processing chamber 207. Further, the clearance between the shower plate 208 and the top of reactor 206 constitutes a buffer chamber 210 in which the processing gas is supplied and diffused, wherein the buffer chamber 210 and the multiple gas feed holes 235 are communicated, so that the bias of distribution of the processing gas introduced through the gas feed holes 235 to the processing chamber 207 is reduced by passing the buffer chamber 210.

According to the present embodiment, the buffer chamber 210 is communicated with a processing gas feed path 224 which is a gas feed pipe, and is further communicated through the processing gas feed path 224 with a processing gas source 220. Below the processing chamber 207 and at a position opposing to the shower plate 208 above a supporting device 214 is disposed a stage including a sample stage 213 on which a sample to be subjected to processing is placed. A high frequency power supply 215 is connected to the lower portion of the sample stage 213, through which power is supplied. According to the present embodiment, a dielectric cylindrical member 211 is formed to cover the inner side wall surface of the processing reactor 201, and an earth member 212 functioning as an earth electrode with respect to the plasma generated in the processing chamber 207 is disposed below the cylindrical member 211 supporting the same. Further, the processing reactors 201 and 202 are grounded via predetermined means.

The earth member 212 is mounted to processing reactors 201 or 202 and comprises a cylindrical flange portion extended downward from the lower end thereof, wherein the gas inside the processing chamber 207 travels downward through the space between the flange portion and the sample stage 213. Thus, the bias of flow of supplied processing gas moving downward through the outer circumference of the sample stage 213 with respect to the circumferential direction of the sample stage 213 and the sample is reduced, and thus, the bias of processing of the sample by plasma is reduced.

A vacuum pump for evacuating and decompressing the interior of the vacuum chamber 216 within the processing reactor 202 and the processing chamber 207 within the processing chamber 201 is arranged below the processing reactor 202. The vacuum pump comprises a dry pump 232 for evacuating air and decompressing the interior of the processing chamber 207 and the vacuum chamber 216 from atmospheric pressure, a turbo molecular pump 231 disposed on an upstream side of the dry pump 232 for further evacuating air from the decompressed state to realize a predetermined high vacuum state, and a variable valve 230 for controlling the communication between the turbo molecular pump 231, the processing reactor 202 and the vacuum chamber 216 by varying the opening of the passage. By adjusting the size of the opening via the operation of the variable valve 230 and by controlling the evacuation performance of the turbo molecular pump 231 and the dry pump 232, it becomes possible to control the evacuation speed and to thereby control the pressure within the processing chamber 207 and the vacuum chamber 216.

Furthermore, as for the vacuum transfer reactor 112, a vacuum pump for decompressing the interior of the vacuum transfer chamber 217 through which the sample is transferred in decompressed state within the vacuum transfer reactor 112 is stuck to the lower portion of the vacuum transfer reactor 112. The vacuum pump is arranged to decompress the pressure of the vacuum transfer chamber 217 to substantially the same pressure as that of the vacuum chamber 216 or the processing chamber 207 through a turbo molecular pump 219.

Furthermore, the vacuum transfer reactor 112 has an inert gas feed path 229 connected to the lower portion thereof for introducing inert gas to the vacuum transfer chamber 217. The inert gas feed path 229 is communicated via a connecting pipe 227 to an inert gas source 225, and the pressure within the vacuum transfer chamber 217 is controlled to a predetermined pressure by the operation of a mass flow controller 226 for controlling the flow rate of inert gas and a supply valve 228.

The processing gas is fed from a gas cylinder and the like provided in the processing gas source 220 and through the operation of a mass flow controller 221 functioning as a flow rate controller connected via a connecting pipe 222 and a feed valve 223 disposed on the lower stream side thereof, the gas flow through the processing gas feed path 224 is controlled and fed to the processing chamber 207 within the vacuum reactor 103. Although not shown in FIG. 2, the processing gas source 220, the connecting pipe 222, the mass flow controller 221 and the feed valve 223 are composed of a plurality of paths enabling a plurality of gases to be fed independently with controlled flow rates, and the present embodiment is also equipped with a path for introducing Ar or N₂ into the processing chamber 207 within the vacuum reactor 103. The plurality of paths are connected via a converged pipe portion 236 to the processing gas feed path 224.

Further, the pressure within the processing reactor 201 or the processing reactor 202 of the vacuum reactor 103 is controlled by adjusting the supply of processing gas and the evacuation performed by the vacuum pump, and the pressure within the processing reactors 201 and 202 is detected by a pressure sensor 233 equipped to the processing reactor 202. The detected pressure is sent to a control unit 234 connected thereto, and the control unit 234 connected to the above-mentioned mass flow controller 221, the feed valve 223, the variable valve 230 and other operating parts controls the processes and operations of the vacuum reactor 103.

The present invention suppresses the particles stuck to the samples, the particles generated by the opening and closing movement of the gate valve 218 during transfer of the substrates such as semiconductor wafers from the vacuum transfer chamber 217 to the processing chamber 207 or from the processing chamber 207 to the vacuum transfer chamber 217 or by the change in pressure due to argon gas (hereinafter referred to as Ar gas) pressurized in the vacuum transfer chamber 217 flowing into the processing chamber 207 during the opening and closing of the gate valve.

The present inventors have examined ways to reduce the number of particles stuck to the sample being the object of processing when transferring the sample within the vacuum processing apparatus 100 having the structure described above.

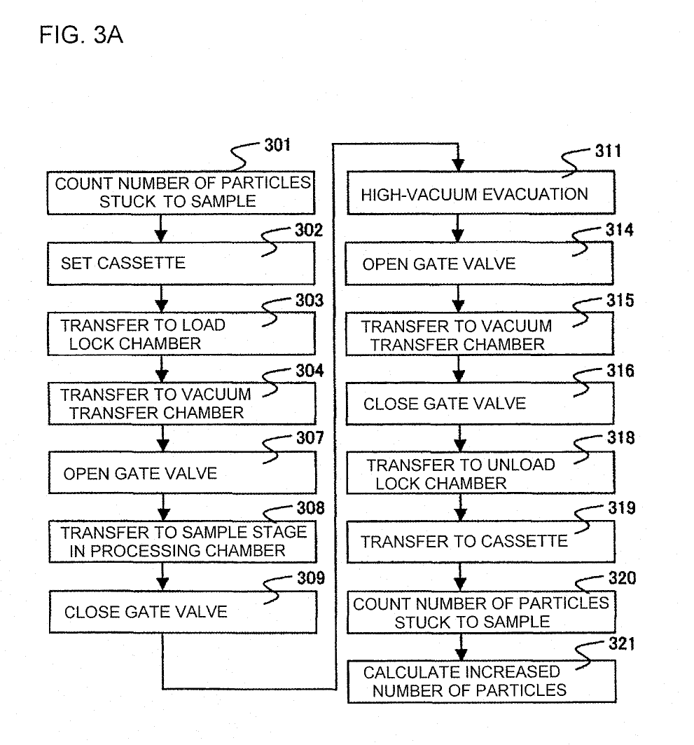

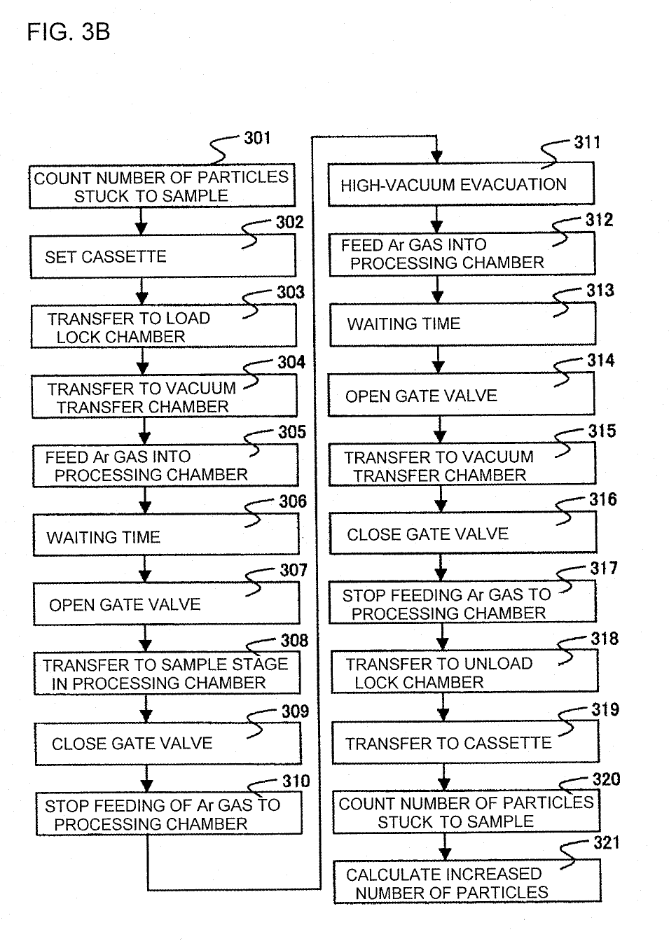

FIG. 3A discloses a step for counting particles which was performed to examine ways to reduce the number of particles. According to the sequential steps performed, the number of particles stuck to the sample in advance is counted in step 301, the sample having the stuck particles counted in step 302 is set to a given cassette 110 in the atmospheric block 102 in step 302, the sample is transferred to the load lock chamber 105 in step 303, the sample is transferred to the vacuum transfer chamber 217 in step 304, the gate valve 218 is opened in step 307, the sample is transferred to a sample stage 213 in the processing chamber 207 in step 308, the gate valve 218 is closed in step 309, and the processing chamber 207 is subjected to high-vacuum evacuation for 60 seconds in step 311. Thereafter, the gate valve 218 is opened in step 314, the sample on the sample stage 213 is transferred to the vacuum transfer chamber 217 in step 315, and the gate valve 218 is closed in step 316. Further, the sample transferred to the vacuum transfer chamber 217 is transferred to the unload lock chamber 106 in step 318, and returned to the cassette 110 in the atmospheric block 102 in step 319. Thereafter, the number of particles existing on the sample is counted in step 320, the difference in number between the number of particles counted in step 320 and the number of particles counted in advance in step 301 is calculated, and the difference in the number of particles is set as the number of particles stuck in the present vacuum processing apparatus. Here, Ar gas was flown in the vacuum transfer chamber 217 and the pressure therein was set to 15 Pa.

Further, prior to performing the examination, a sample having counted the number of particles stuck thereto in advance was set to a given cassette 110 in the atmospheric block 102, and the initial number of particles in the vacuum processing apparatus was confirmed in the steps of FIG. 3A. However, the transfer of the sample to the processing chamber 207 was not performed, and the number of particles in the path to the vacuum transfer chamber was counted. The sample having the number of particles stuck thereto counted in advance was transferred from the load lock chamber 105 to the vacuum transfer chamber 217, and thereafter, the sample in the vacuum processing chamber 217 was returned from the unload lock chamber 106 to the cassette 110 in the atmospheric block 102. It was confirmed for a few times that the number of particles stuck to the sample in this set of operations was zero to three for particles with a particle size of 0.13 μm or greater, and it was confirmed that according to the status of the apparatus, the number of particles stuck to the sample when the sample was not transferred to the processing chamber 207 and the gate valve 218 was opened and closed was, although somewhat dispersed, three or smaller for particles with a particle size of 0.13 μm or greater. Further, the confirmation was also performed during the period of time in which the examination was performed, and it was confirmed that the device maintained a status in which there was no increase in the number of particles.

During the examination for reducing particles, a status was realized so that there was a constant amount of particles generated by adhering particles as particles source to the surrounding area of the gate valve 218 within the processing chamber 207. Particles as particle source 237 were stuck to the position shown in FIG. 2. Further, a 12-inch sample was used in the present examination.

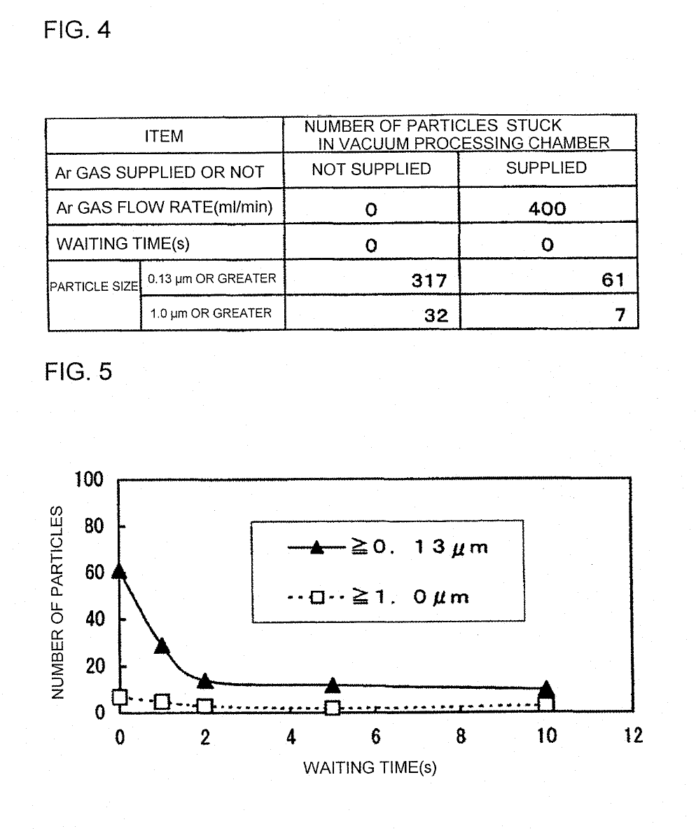

In the vacuum processing apparatus 100 of the above-mentioned status, the sample having the number of particles stuck thereto counted in advance was transferred according to the steps shown in FIG. 3A. Since the processing chamber 207 is controlled to a given pressure normally when the sample is transferred thereto and processing gas is fed to start processing, the opening of the variable valve 230 will be varied, but the opening of the valve is set to 100 percent or fully opened state when the feeding of processing gas has terminated and the processing is not performed. Therefore, the sample was transferred with the variable valve 230 opened for 100 percent. The pressure within the processing chamber 207 when the variable valve 230 is opened for 100 percent and evacuation is performed by the turbo molecular pump 231 is as low as 0.1 Pa or smaller. The number of particles stuck to the sample in advance is counted in step 301, the sample having the particles counted in step 302 is set to a given cassette 110 in the atmospheric block 102 in step 302, the sample is transferred to the load lock chamber 105 in step 303, the sample is transferred to the vacuum transfer chamber 217 in step 304, the gate valve 218 is opened in step 307, the sample is transferred to a sample stage 213 in the processing chamber 207 in step 308, the gate valve 218 is closed in step 309, and the processing chamber 207 is subjected to high-vacuum evacuation for 60 seconds in step 311. Thereafter, the gate valve 218 is opened in step 314, the sample on the sample stage 213 is transferred to the vacuum transfer chamber 217 in step 315, and the gate valve 218 is closed in step 316. Further, the sample transferred to the vacuum transfer chamber 217 is transferred to the unload lock chamber 106 in step 318, and returned to the cassette 110 in the atmospheric block 102 in step 319. Thereafter, the number of particles existing on the sample is counted in step 320, the difference in the number between the number of particles counted in step 320 and the number of particles counted in advance in step 301 is calculated, and the difference in the number of particles is set as the number of particles stuck according to the present vacuum processing apparatus. According to this set of operations, the number of particles stuck to the sample was, as illustrated in FIG. 4, 317 for particles with a particle size of 0.13 μm or greater, and 32 for particles with a particle size of 1.0 μm or greater. The evaluation was performed for particles with a particle size of 0.13 μm or greater and a particle size of 1.0 μm or greater, since currently in the dry-processing mass production of 12-inch semiconductor substrates, the managing of particles are performed for particles with a particles size of 0.13 μm or greater and a particle size of 1.0 μm or greater.

Next, particles were counted according to a similar step in which Ar gas was flown into the processing chamber 207 prior to opening and closing the gate valve 218 during transfer of the samples. The steps are shown in FIG. 3B. The flow rate of the flown Ar gas was set to 400 ml/min. The pressure in the processing chamber 207 at that time was 0.32 Pa. According to the steps shown in FIG. 3B, a sample having counted the number of particles stuck thereto in advance was transferred. Normally in the processing chamber 207, the pressure is controlled to a predetermined pressure by changing the opening of the variable valve 230 when the sample is transferred and processing gas is supplied to start the processing, but the opening of the valve is set to 100 percent or at fully opened state when the supply of processing gas is terminated and processing is not performed. Therefore, the sample was transferred with the variable valve 230 opened for 100 percent. The pressure within the processing chamber 207 with the variable valve 230 opened for 100 percent and evacuation performed via the turbo molecular pump 231 prior to supplying 400 ml/min of Ar gas is as low as 0.1 Pa or smaller.

According to the sequential steps performed in FIG. 3B, the number of particles stuck to the sample in advance is counted in step 301, the sample having the number of particles counted in step 302 is set to a given cassette 110 in the atmospheric block 102 in step 302, the sample is transferred to the load lock chamber 105 in step 303, the sample is transferred to the vacuum transfer chamber 217 in step 304, an Ar gas is supplied through gas feed holes of the shower plate 208 into the processing chamber 207 in step 305, a certain waiting time is elapsed in step 306, the gate valve 218 is opened in step 307, the sample is transferred to a sample stage 213 in the processing chamber 207 in step 308, the gate valve 218 is closed in step 309, the supply of Ar gas to the processing chamber 207 is stopped in step 310, and the processing chamber 207 is subjected to high-vacuum evacuation for 60 seconds in step 311. Thereafter, Ar gas is supplied to the processing chamber 207 in step 312, a certain waiting time is elapsed in step 313, the gate valve 218 is opened in step 314, the sample on the sample stage 213 is transferred to the vacuum transfer chamber 217 in step 315, the gate valve 218 is closed in step 316, and the supply of Ar gas to the processing chamber 207 is stopped in step 317. Further, the sample transferred to the vacuum transfer chamber 217 is transferred to the unload lock chamber 106 in step 318, and returned to the cassette 110 in the atmospheric block 102 in step 319. Thereafter, the number of particles existing on the sample is counted in step 320, the difference in the number between the number of particles counted in step 320 and the number of particles counted in advance in step 301 is calculated, and the difference in the number of particles is set as the number of particles stuck in the present vacuum processing apparatus. Here, the waiting time in step 306 and in step 313 was set to zero seconds. The number of particles on the sample was, as shown in FIG. 4, 61 for particles with a particle size of 0.13 μm or greater and 7 for particles with a particles size of 1.0 μm or greater.

FIG. 5 shows the number of particles on the sample when Ar gas flow is set to 400 ml/min and the waiting time from the start of supply of Ar gas to the opening of the gate valve 218 varied. The process of the experiment was performed according to FIG. 3B. It was discovered that the number of particles was reduced when a waiting time was set, and that the number of particles was greatly reduced when the waiting time was set to two seconds or greater.

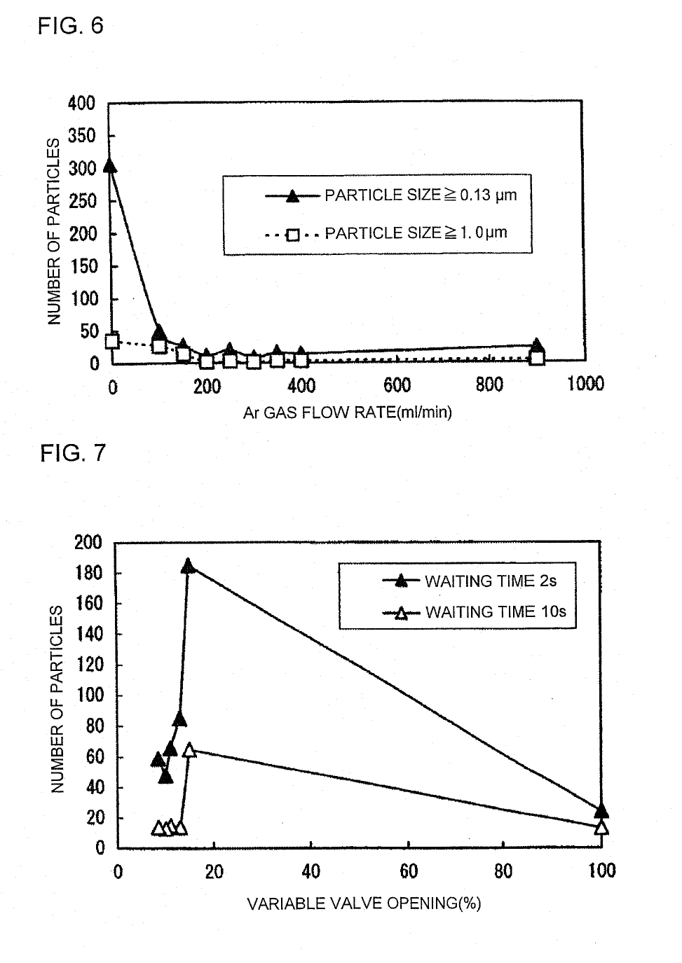

FIG. 6 shows the result of Ar gas flow dependency with the waiting time set to two seconds. It was discovered that the number of particles was reduced by increasing the Ar gas flow rate, and was reduced significantly when the flow rate was set to 200 ml/min or greater, wherein the number of particles with a particles size of 0.13 μm was approximately 20, and the number of particles with a particles size of 1.0 μm was five or smaller. The pressure in the processing chamber 207 when Ar gas flow is set to 200 ml/min was 0.13 Pa, the Ar gas flow rate in the processing chamber 207 was 200 ml/min, and the average flow velocity was 17.6 m/sec.

FIG. 7 shows the variable valve opening dependency with the opening of the variable valve 230 varied and with the waiting time set to either 2 s or 10 s and the Ar gas flow rate set to 900 ml/min. The particle size was 0.13 μm or greater. When the waiting time was set to 2 s, the number of particles was increased when the variable valve 230 was moved, but when the waiting time was set to 10 s, the number of particles was reduced. However, it is considered that the influence of the movement of the variable valve 230 still remains if the pressure difference between the processing chamber 207 and the vacuum transfer chamber 217 is great. In other words, even if Ar gas is supplied, when the variable valve 230 is moved, the influence of the movement of the variable valve 230 causes the waiting time to be set longer, which deteriorates the processing efficiency.

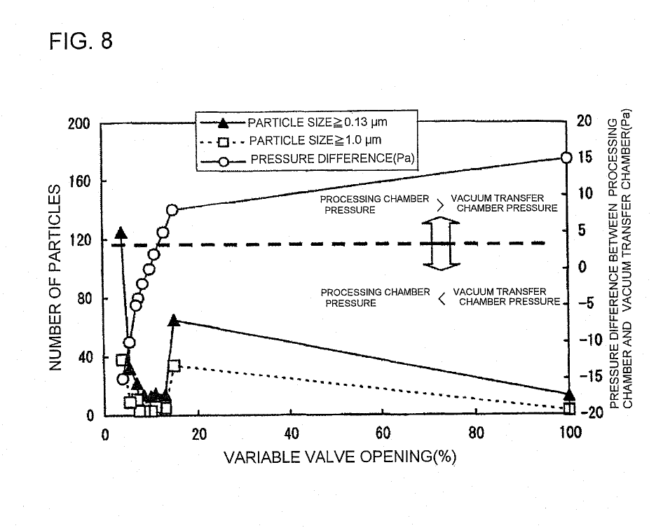

Next, an example was examined in which the Ar gas flow rate was set to 900 ml/min and the opening of the variable valve 23 was varied so that the pressure in the processing chamber 207 was set higher by 15 Pa than the pressure in the vacuum transfer chamber 217. FIG. 8 shows the result. In order to eliminate the influence of movement of the variable valve 230, the waiting time from the starting of supply of Ar gas to the opening of the gate valve 218 was set to 10 seconds. Even if the pressure within the processing chamber 207 is high, there is no significant influence when the difference in pressure between the processing chamber 207 and the vacuum transfer chamber 217 is 5 Pa or smaller, however, when the difference exceeds 5 Pa, the number of particles stuck to the sample increases significantly. In other words, unless the pressure in the processing chamber 207 is set lower than the pressure in the vacuum transfer chamber 217, the number of particles increases even if a long waiting time is set, so it has been discovered that the pressure in the processing chamber 207 must be set lower than the pressure in the vacuum transfer chamber 217.

Based on the above examination results, the present inventors have reached the following conclusion.

When a sample is transferred between the vacuum transfer chamber 217 and the processing chamber 207 of the vacuum reactor 103, if there is a difference in pressure between the vacuum transfer chamber 217 and the processing chamber 207, particles are generated instantaneously when the gate valve 218 is opened due to the movement of the gate valve 218 and the pressure difference, and the particles are stuck to the sample being transferred causing the number of particles on the sample to be increased, but when an Ar gas flow with a flow rate of 200 ml/min or greater is formed in the processing chamber 207 and the gate valve 218 is opened and closed after waiting for 2 seconds or more after starting the Ar gas supply, the number of particles stuck to the transferred sample will not increase. This is considered to have been realized by the particles generated by the gate valve movement or pressure difference being evacuated by the Ar gas flow of 200 ml/min or greater formed in the processing chamber 207 during the waiting time of 2 seconds, and the generated particles being unable to reach the sample by resisting against the Ar gas flow since Ar gas is continuously flown in the processing chamber forming an Ar gas flow until the transfer of the sample is terminated and the gate valve 218 is closed.

Furthermore, when the sample is transferred between the vacuum transfer chamber 217 and the processing chamber 207 in the vacuum reactor 103, the number of particles stuck to the sample is small when there is little pressure difference between the vacuum transfer chamber 217 and the processing chamber 207, but since time is required for the pressure to reach a predetermined pressure, the processing efficiency is deteriorated. Further, particles are generated when the variable valve 230 is moved, and the influence thereof remains for at least two seconds. Therefore, it is desirable that the movement of the variable valve 230 is minimized.

As illustrated in the embodiment mentioned above, upon transferring the sample which is the object of processing between the vacuum reactor and the transfer reactor, the variable valve for controlling pressure disposed at a lower portion of the vacuum reactor is opened for 100 percent to depressurize the interior of the vacuum reactor, and thereafter, Ar gas is supplied through the feed holes into the vacuum reactor without changing the opening of the pressure controlling variable valve so as to form an Ar gas flow of 200 ml/min or greater so that the pressure in the processing chamber is set smaller than the pressure in the vacuum transfer chamber. In this state, the gate valve is opened and the sample is transferred. The gate valve is closed after transferring the sample, and thereafter, the supply of Ar gas is stopped. According to this arrangement, it becomes possible to provide a vacuum processing apparatus capable of reducing the particles stuck to the sample without practically deteriorating the efficiency of the process since only two seconds of waiting time is required.

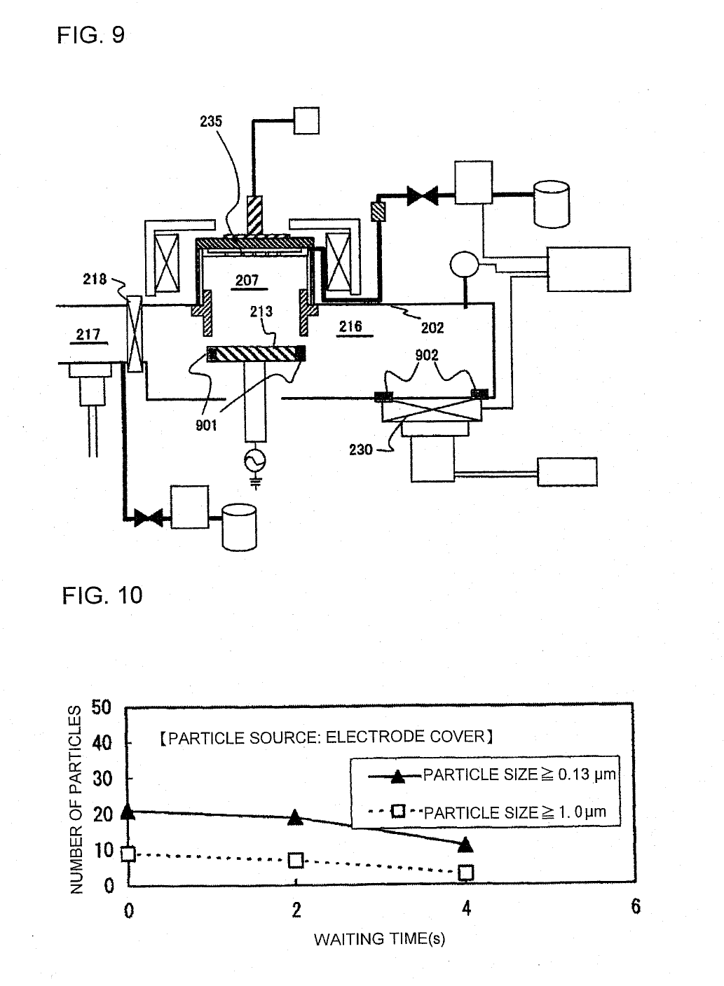

The effect of supplying an Ar gas flow during transfer was further confirmed by changing the position of sticking the particle source, by removing the particle source 237 in FIG. 2 and sticking either a particle source 901 on the side surfaces of the sample stage 213 in the processing chamber 207 or by sticking a particle source 902 in the circumference portion of the variable valve 230. The sticking positions of the particle sources are shown in FIG. 9. Further, the particle source 901 and the particle source 902 are not stuck simultaneously, but stuck for independent examinations.

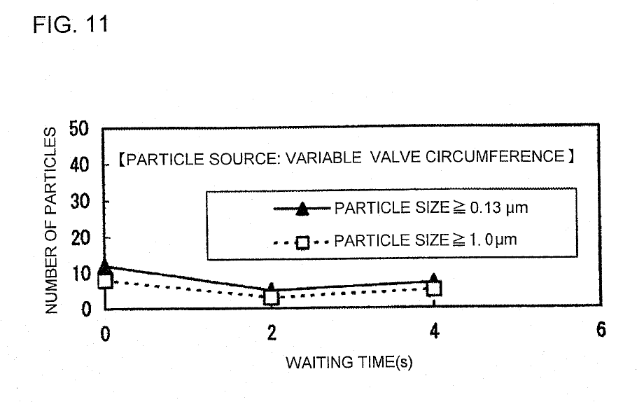

FIGS. 10 and 11 illustrate the number of particles on the sample when the Ar gas is set to 200 ml/min with the waiting time from the starting of supply of the Ar gas flow to the opening of the gate valve 218 varied. FIG. 10 corresponds to the case in which the particle source 901 is stuck to the side surfaces of the sample stage 213. FIG. 11 corresponds to the case in which the particle source 902 is stuck to the circumference portion of the variable valve 230. The number of particles was reduced since a waiting time is set, and it was confirmed that the number of particles was greatly reduced when the waiting time was set to two seconds or longer, and that the same effect was achieved with the position of the particle source varied.

According to the present embodiment, plasma is generated using an ECR formed by electromagnetic waves in the UHF band and a magnetic field formed via solenoid coils, but the method of generating plasma is not restricted to the method disclosed in the embodiment, and plasma generated by other plasma generation methods such as a conductively-coupled plasma generating method, an inductively-coupled plasma generating method and a microwave-ECR plasma generation method can be used. Further, it is considered that the flow of gas other than Ar, such as N₂ gas and other inert gases or processing gases formed in the processing chamber enables to realize equivalent effects.

The above embodiment was described taking a plasma etching apparatus as an example, but the present invention can be applied widely to any processing apparatus having a gate valve for opening and closing a passage communicating a vacuum transfer chamber and a processing chamber in a vacuum reactor. Examples of the processing apparatus to which the present invention can be applied include other processing apparatuses using plasma such as a plasma CVD apparatus and processing apparatuses not utilizing plasma such as an ion implantation apparatus, an MBE apparatus and a decompressed CVD apparatus.

As described above, upon transferring the sample to be processed between the vacuum reactor and the transfer reactor, the present embodiment opens the variable valve for adjusting pressure disposed at a lower portion of the vacuum reactor to 100 percent to decompress the interior of the vacuum reactor, and thereafter, supplies Ar gas through the feed holes into the vacuum reactor without changing the opening of the variable valve for adjusting pressure to form an Ar gas flow of 200 ml/min or greater so that the pressure within the processing chamber is lower than the pressure within the vacuum transfer chamber, and in this state, opens the gate valve to perform transfer of the sample, and after transferring the sample and closing the gate valve, stopping the supply of Ar gas. Thus, the present embodiment provides a vacuum processing apparatus capable of reducing the particles stuck to the sample and substantially not deteriorating the process efficiency since only a waiting time as short as two seconds is required.

1. (canceled)

2. (canceled)

3. A vacuum processing method using a vacuum processing apparatus comprising:
a processing chamber disposed within a vacuum reactor and having plasma generated therein;
a sample stage disposed at a lower portion within the processing chamber for mounting on an upper surface thereof a sample to be processed;
a gas feed mechanism disposed at an upper portion of the processing chamber and having a feed hole for feeding processing gas into the processing chamber;
a transfer reactor connected to the vacuum reactor for having the sample to be processed transferred in the decompressed interior thereof; and
a gate valve for opening and closing a passage communicating the transfer reactor and the vacuum reactor;
wherein the vacuum processing method comprises, upon transferring the sample to be processed between the transfer reactor and the vacuum reactor;
setting an opening of a variable valve for controlling pressure disposed below the vacuum reactor to a predetermined opening so as to decompress the interior of the vacuum reactor;
feeding a predetermined amount of gas through the feed hole into the vacuum reactor and forming a gas flow without varying the opening of the variable valve for controlling pressure; and
opening the gate valve in this state to transfer the sample, closing the gate valve after transferring the sample and stopping the feeding of gas thereafter.

4. The vacuum processing method using a vacuum processing apparatus according to claim 3, wherein the gas fed into the vacuum reactor is either Ar gas or N₂ gas, the formed gas flow has a flow rate of 200 ml/min or greater, and the pressure within the vacuum reactor is lower than the pressure within the transfer reactor connected thereto.

5. The vacuum processing method using a vacuum processing apparatus according to claim 3, wherein the transfer of the sample is started when at least two seconds has passed after forming the gas flow.
